(19) United States
(12) Patent Application Publication
(10) Pub. No.: US 2008/0157354 A1
(43) Pub. Date: Jul. 3, 2008

(54) Multiple stacked nanostructure arrays and methods for making the same

(75) Inventors: Fengyan Zhang, Vancouver, WA (US); Sheng Teng Hsu, Camas, WA (US)

Correspondence Address: David C. Ripma;Sharp Laboratories of America, Inc., 5750 NW Pacific Rim Boulevard, Camas, WA, 97202, US

(73) Assignee: Sharp Laboratories of America, Inc.

(21) Appl. No.: 11/649,523

(22) Filed: Jan. 3, 2007

(51) Int. Cl. H01L 27/00; H01L 21/02

(52) U.S. Cl. 257/734; 438/763; 438/48; 438/652; 977/953; 257/E27.001; 257/E21.002

(57) ABSTRACT

A method of fabricating a stacked nanostructure array includes preparing a substrate; forming a bottom electrode directly on the substrate; growing a first nanostructure array directly on the bottom electrode; forming an insulating layer on the first nanostructure array; exposing the upper surface of the first nanostructure array; depositing a second, and subsequent, nanostructure array on a nanostructure array immediately below the second and subsequent nanostructure array; repeating said forming, said exposing and said depositing a subsequent steps to form a stacked nanostructure array; removing an uppermost insulating layer; and forming a top electrode on an uppermost nanostructure array. A sensor incorporating the nanostructure array includes top and bottom electrodes with plural layers of nanostructure array therebetween.

### FIELD OF THE INVENTION

This invention relates to fabrication of vertically stacked, multiple nanostructure arrays, and to very small control devices, and specifically to control devices which incorporate a variety of nanostructures.

### BACKGROUND OF THE INVENTION

A number of different materials have been investigated as components of nanostructure devices. The materials include semiconductors, metals, oxides, compounds, and even polymers. High aspect ratio single crystalline IrO₂ nanowires and TiO₂ nanorods array have been fabricated, as previously disclosed in U.S. patent application Ser. No. 11/582,197, filed Oct. 16, 2006, for Solar Cell Structures using Porous Column TiO₂ Films deposited by CVD, and U.S. Patent Publication No. 2006/0086314-A1, published Apr. 27, 2006, for Iridium Oxide Nanowires and Method for Forming Same, which are incorporated herein by reference. The single crystal IrO₂ nanowire is conductive and may be used as an electrode, while TiO₂ nanorods have applications in sensors and solar cells.

Although different materials have been explored, known works are limited to use of a single type of nanostructure, using a single type of material. There is no known report on the use of multiple materials or on stacked nanostructures, wherein the stacked nanostructures are of different structural types.

### SUMMARY OF THE INVENTION

A method of fabricating a stacked nanostructure array includes preparing a substrate; forming a bottom electrode directly on the substrate; growing a first nanostructure array directly on the bottom electrode; forming an insulating layer on the first nanostructure array; exposing the upper surface of the first nanostructure array; depositing a second, and subsequent, nanostructure array on a nanostructure array immediately below the second and subsequent nanostructure array; repeating said forming, said exposing and said depositing a subsequent steps to form a stacked nanostructure array; removing an uppermost insulating layer; and forming a top electrode on an uppermost nanostructure array. A sensor incorporating the nanostructure array includes top and bottom electrodes with plural layers of nanostructure array therebetween.

It is an object of the invention to provide a stacked array of nanostructures.

Another object of the invention is to fabricate a stacked array of nanostructures having different base material therein.

A further object of the invention is to fabricate a stacked array of nanostructures having different nanostructure components.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a block diagram of the method of the invention.

FIG. 2 depicts a sensor structure fabricated according to the method of the invention.

FIGS. 3 and 4 depict stacked IrO₂ nanowires fabricated on top of a TiO₂ nanorod array.

### DETAILED DESCRIPTION OF THE PREFERRED EMBODIMENTS

A vertical stacked, multiple nanostructure array is disclosed as an example of the method of the invention hereof. A stacked nanostructure fabricated according to the method of the invention has applications as an efficient and cost effective control device, and in environment controls, energy generation, energy storage, and various types of sensors.

The method of the invention provides a technique for fabricating a device wherein a nanostructured material is stacked on top of the another nanostructured material, while still maintaining vertical continuity and lateral porous structure of the entire stack.

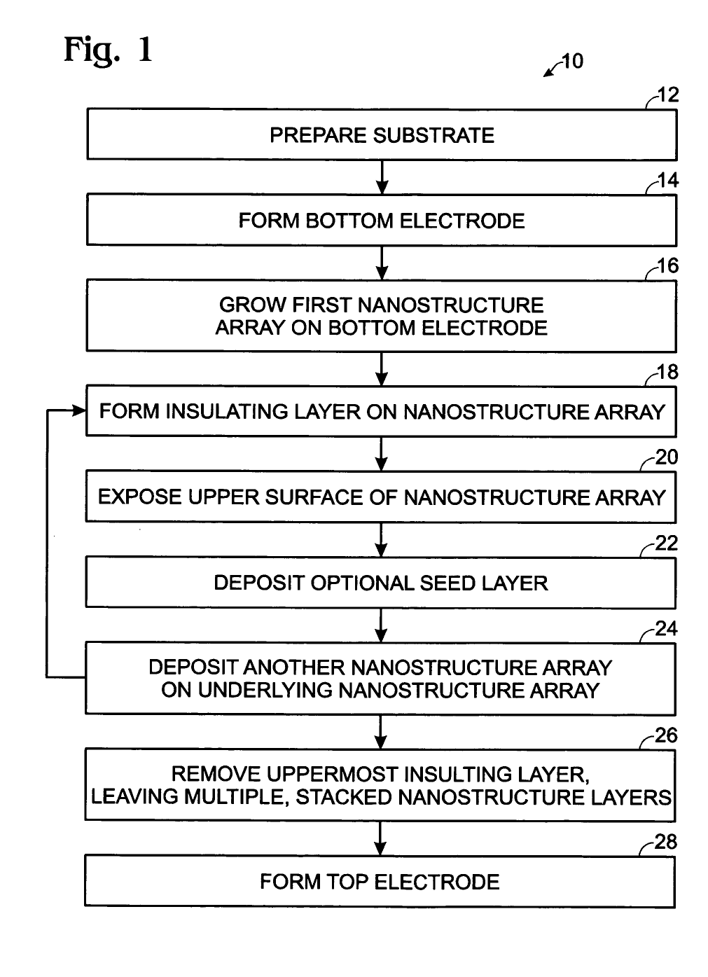

Referring now to FIG. 1, the method of the invention is depicted generally at 10. A substrate is prepared, 12. Substrate 12 may be silicon, glass, a flexible substrate, etc. A bottom electrode is formed 14 on the substrate, which electrode may be Au, Pt, TiN, TaN, Ir, ITO, SnO₂, Cu, Mo, ZnO, polysilicon, etc. A first, or lower, nanostructure array is formed 16 on the bottom electrode, details of which will be explained later herein.

In order to prevent the next nanostructure array material from being deposited into the pores present in the bottom nanostructure array, an insulating layer is formed 18, which may be silicon-on-glass (SOG), and which may be formed by spin coating onto the bottom nanostructure array. A curing process, subsequent etching or CMP process, is performed 20 to expose the tips of the bottom nanostructure array layer.

An optional seed layer may be deposited 22 prior to subsequent nanostructure array formation. The purpose of the seed layer is to promote nanostructure array formation on any lower nanostructure array and to maintain the continuity of the stacked nanostructure arrays.

A nanostructure array is deposited 24 on the first nanostructure array, and the next insulating layer is then deposited, as in step 18. This process continues through steps 20, 22 until all the nanostructure layers have been deposited.

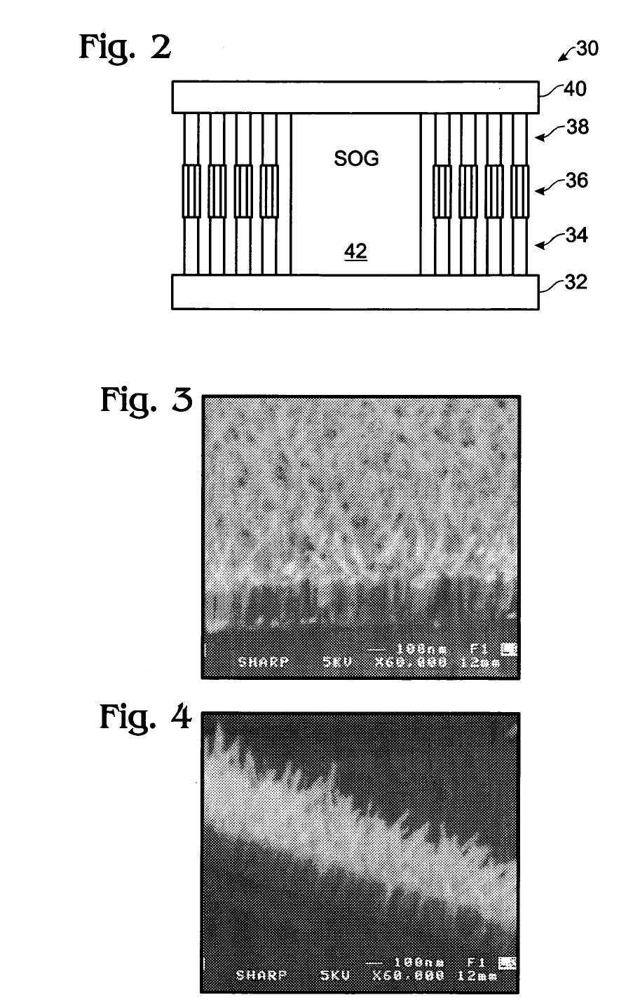

After all the nanostructure arrays are deposited, the uppermost insulating layer may be removed 26, as by selective etching, leaving the stand-alone, multiple stacked nanostructure array. A top electrode is formed on the uppermost nanostructure layer 28. A stacked nanowire array fabricated according to the method of the invention is depicted in FIG. 2, generally at 30. Array 30 includes a bottom electrode 30, a first nanostructure array 32, a second nanostructure array 34, and a third nanostructure array 36, which are capped by a top electrode 40. A central insulating structure 42 remains.

The process conditions to grow TiO₂ nanorods array is the same as disclosed in U.S. patent application Ser. No. 10/971,330, filed Oct. 24, 2004, for Iridium Oxide Nanowires and Method for Forming Same. After TiO₂ nanorod array formation, the wafer is placed in a growth chamber for IrO₂ nanowire formation. The condition to grow IrO₂ nanowires is the same as disclosed in U.S. patent application Ser. No. 11/582,197, filed Oct. 16, 2006, for Solar Cell Structures using Porous Column TiO₂ Films deposited by CVD.

Nanomaterials which may be stacked on top of each other may be of different nanostructure forms, such as nanowires, nanotubes, nanorods, nanoparticles, nanobelts, nanocombs, 3D nanostructures, etc. The nanostructures may also be of different densities in the array and have different diameters. The nanomaterial include, but not limited to, TiO₂, ZnO, SnO₂, Sb₂O₃, In₂O₃, WO₃, and carbon. Additionally, carbon nanotubes, metal nanowires, such as Pd, Pt, Au, Mo, and semiconductor nanowires such as Si, Ge, SiGe, CdSe, AlN, ZnS, GaN, InP, InAs, PbSe, PbS, and IrO₂, etc., may be stacked in the stacked nanostructure array fabricated according to the method of the invention.

This vertical stacked nanowires arrays structure may be used for environment control, energy generation, energy storage and sensor applications. A gas sensor application is described in U.S. patent application Ser. No. 11/264,113, filed Nov. 1, 2005, for Ambient Environment Nanowire Sensor, incorporated herein by reference, which uses an IC compatible process to fabricate nanowire array sensor structure. The structure includes a single stack nanowire array that may be coated with different materials for different sensing capabilities. In this invention, the single nanowire array is replaced by multiple stacked nanowire arrays. After all the nanowires arrays have been deposited, and the SOG has been deposited, the very top layer of the SOG is removed, by etching or CMP, to expose the tips of the top nanowire array. The top electrode is deposited and a stack etching is performed. After the stack etching, a selective etching of the SOG is performed to expose the outer rim of the stacked nanowire arrays. The center region of SOG is left, in situ, to support the structure. These procedures are similar to the process that has been disclosed in the above-identified pending application for a single nanostructure array.

Because the exposed outer rim of the nanostructure stack has different sensing materials exposed to the ambient atmosphere, each of the nanomaterials sense a different gas(es), resulting in a much broader sensing spectrum for the sensor.

Stacked nanostructure arrays are depicted in FIGS. 3 and 4, wherein IrO₂ nanowires are stacked on top of a TiO₂ nanorod array. It can be seen that a rather dense single-crystal IrO₂ nanowire array is grown on top of the TiO₂ nanorod array. Although the size and density are different, the two layers are well separated, and maintain vertical continuity.

Thus, a method to from a stacked nanostructure device has been disclosed. It will be appreciated that further variations and modifications thereof may be made within the scope of the invention as defined in the appended claims.

We claim:

1. A method of fabricating a stacked nanostructure array, comprising:
preparing a substrate;
forming a bottom electrode directly on the substrate;
growing a first nanostructure array directly on the bottom electrode;
forming an insulating layer on the first nanostructure array;
exposing the upper surface of the first nanostructure array;
depositing a second, and subsequent, nanostructure array on a nanostructure array immediately below the second and subsequent nanostructure array;
repeating said forming, said exposing and said depositing a subsequent steps to form a stacked nanostructure array;
removing an uppermost insulating layer; and
forming a top electrode on an uppermost nanostructure array.

2. The method of claim 1 which includes, after said exposing, forming a seed layer on a nanostructure array to facilitate formation of a next nanostructure array thereon.

3. The method of claim 1 wherein the nanostructures in an array have a different structure than the nanostructures in an adjacent array.

4. The method of claim 1 wherein the nanostructures in an array are formed of a different material than the nanostructures in an adjacent array.

5. The method of claim 1 wherein said forming an insulating layer includes forming a SOG insulating layer by spin coating.

6. A method of fabricating a stacked nanostructure array, comprising:
preparing a substrate;
forming a bottom electrode directly on the substrate;
growing a first nanostructure array directly on the bottom electrode;
forming an insulating layer on the first nanostructure array;
exposing the upper surface of the first nanostructure array;
depositing a second nanostructure array on the first nanostructure array;
forming an insulating layer on the second nanostructure array;
exposing the upper surface of the second nanostructure array;
forming a top electrode on the second nanostructure array.

7. The method of claim 6 which includes, after said exposing, forming a seed layer on a the first nanostructure array to facilitate formation of the second nanostructure array.

8. The method of claim 6 wherein the first nanostructures array has a different structure than the nanostructures in the second array.

9. The method of claim 6 wherein the nanostructures in the first array are formed of a different material than the nanostructures in the second array.

10. The method of claim 6 wherein said forming an insulating layer includes forming a SOG insulating layer by spin coating.

11. A stacked nanostructure array, comprising:
a substrate;
a bottom electrode formed directly on the substrate;
a first nanostructure array formed directly on the bottom electrode;
an insulating layer formed on said first nanostructure array, and partially removed to expose the upper surface of said first nanostructure array;
a second nanostructure array formed on said first nanostructure array and similarly insulated and exposed;
forming a top electrode on said second nanostructure array.

12. The array of claim 11 which further includes a seed layer formed on said first nanostructure array to facilitate formation of said second nanostructure array.

13. The array of claim 11 wherein said first nanostructures array has a different structure than the nanostructures in said second array.

14. The array of claim 11 wherein the nanostructures in the said array are formed of a different material than the nanostructures in said second array.

15. The array of claim 6 wherein said insulating layer is a SOG insulating layer, formed by spin coating.

16. The array of claim 11 wherein the nanostructures are taken form the group of nano structures consisting of such as nanowires, nanotubes, nanorods, nanoparticles, nanobelts, nanocombs, 3D nanostructures, carbon nanotubes, metal nanowires, and semiconductor nanowires.

17. The array of claim 11 wherein the materials used to form said nanostructure arrays is taken from the group of materials consisting of TiO₂, ZnO, SnO₂, Sb₂O₃, In₂O₃, WO₃, carbon, Pd, Pt, Au, Mo, Si, Ge, SiGe, CdSe, AlN, ZnS, GaN, InP, InAs, PbSe, PbS and IrO₂.
